(19) United States
(12) Patent Application Publication
(10) Pub. No.: US 2026/0114233 A1
(43) Pub. Date: Apr. 23, 2026

(54) SUPPORT UNIT AND SUBSTRATE PROCESSING APPARATUS INCLUDING SAME

(71) Applicant: SEMES CO., LTD., Cheonan-si (KR)

(72) Inventors: In Ki JUNG, Seongnam-si (KR); Jun Ho SONG, Hwaseong-si (KR); Jae Youl KIM, Yongin-si (KR); Jeong Bo SHIM, Suwon-si (KR); Se Hoon OH, Cheonan-si (KR); Wan Hee JEONG, Suwon-si (KR)

(73) Assignee: SEMES CO., LTD., Cheonan-si (KR)

(21) Appl. No.: 19/361,639

(22) Filed: Oct. 17, 2025

(30) Foreign Application Priority Data
Oct. 17, 2024 (KR) 10-2024-0142418

(51) Int. Cl. H01L 21/687; H01L 21/67

(52) U.S. Cl. CPC H10P 72/7606; H10P 72/0414; H10P 72/7611; H10P 72/7618

(57) ABSTRACT

Disclosed are a support unit and a substrate processing apparatus including the same, which prevent a backflow, a wake, or an upward airflow from occurring around a spin chuck. The support unit and the substrate processing apparatus including the same include: a spin chuck; a guide ring provided to surround the spin chuck; a guide ring is installed under the guide ring, and includes cylindrical support with open top and bottom, and a supporting body installed under the guide ring and having a cylindrical shape with open top and bottom portions, in which the supporting body is provided to surround the side of the spin chuck, and a plurality of discharge ports is formed in the supporting body.

### CROSS-REFERENCE TO RELATED APPLICATION

This application claims priority to and the benefit of Korean Patent Application No. 10-2024-0142418 filed in the Korean Intellectual Property Office on Oct. 17, 2024, the entire contents of which are incorporated herein by reference.

### TECHNICAL FIELD

The present invention relates to a support unit and a substrate processing apparatus including the same, and more specifically, to a support unit used to liquid-treat a substrate and a substrate processing apparatus including the same.

### BACKGROUND ART

The semiconductor process includes a process of cleaning thin films, foreign substances, particles, and the like on a substrate. The cleaning process is performed by placing a substrate on a spin chuck and supplying a treatment liquid to an upper surface of the substrate while rotating a support unit.

The treatment liquid supplied onto the substrate forms a liquid film and reacts with the substrate, but some of the treatment liquid is scattered from the substrate by centrifugal force. In general, since the scattered treatment liquid may cause particles, the scattered treatment liquid is recovered by a cup body having a recovery space. However, since the cup body is spaced apart from the spin chuck by a certain distance, when the rotational speed of the spin chuck increases and the amount of treatment liquid scattered and the scattering range of the treatment liquid scattered from the substrate increase, there is a problem that the treatment liquid cannot be properly recovered. Accordingly, in order to properly recover the treatment liquid, a guide ring for guiding the treatment liquid to the cup body at a position adjacent to the cup body rather than the cup body is required. However, since the guide ring is provided on a transfer path of the substrate, interference with the transfer robot entering the support unit to load in or unload out the substrate has occurred.

In order to solve this problem, a technology for driving the guide ring to move in the vertical direction when the substrate is loaded and unloaded has been proposed. A supporting body is provided under the guide ring to support the guide ring, and the support is driven in the vertical direction by the driver to lower the guide ring when the substrate is loaded, and the guide ring is raised after the substrate is loaded. At this time, the chuck pin may be provided to be driven together.

However, when the supporting body is provided in the form of radiating from the center of the spin chuck on which the substrate is placed, the coupling point where the supporting body and the guide ring are coupled is formed discontinuously. This causes stress to be concentrated at each coupling point when the spin chuck rotates, and causes deformation and vibration of the guide ring due to excessive stress, thereby deteriorating the stability of the apparatus and process.

Additionally, when the spin chuck rotates, the supporting body collides with the surrounding air, which forms a backflow, a wake, or an upward airflow around the supporting body, and the surrounding contaminant substances may be transmitted to the substrate by a backflow, a wake, or an upward airflow, causing contamination of the substrate.

### SUMMARY OF THE INVENTION

The present invention has been made in an effort to provide a support unit capable of minimizing deformation of a guide ring, and a substrate processing apparatus including the same.

The present invention has also been made in an effort to provide a support unit capable of improving apparatus and process stability, and a substrate processing apparatus including the same.

The present invention has also been made in an effort to provide a support unit capable of preventing a backflow, a wake, or an upward airflow from occurring around a spin chuck, and a substrate processing apparatus including the same.

The present invention has also been made in an effort to provide a support unit capable of preventing the generation of particles and contamination of a substrate, and a substrate processing apparatus including the same.

The present invention has also been made in an effort to provide a support unit capable of efficiently recovering a treatment liquid scattered from a rotating substrate, and a substrate processing apparatus including the same.

The present invention has also been made in an effort to provide a support unit capable of discharging the treatment liquid to the outside of a supporting body even when the treatment liquid is scattered into the supporting body, and a substrate processing apparatus including the same.

The objectives of the present disclosure are not limited thereto and other objectives not stated herein may be clearly understood by those skilled in the art from the following description.

An exemplary embodiment of the present disclosure, an apparatus for processing a substrate, the apparatus comprising: a cup body for providing a treatment space for processing a substrate; a support unit for supporting and rotating the substrate in the treatment space; and a liquid supply unit for supplying a treatment liquid to an upper surface of the substrate supported by the support unit, wherein the support unit includes: a spin chuck on which the substrate is placed and rotates; a chuck pin installed on the spin chuck to support a side of the substrate placed on the spin chuck; a guide ring installed on the spin chuck to rotate with the spin chuck; a supporting body for supporting the guide ring and having a cylindrical shape with open top and bottom portions; and a driving assembly for lifting the supporting body so that the guide ring moves relative to the spin chuck in a vertical direction, when viewed from above, the guide ring is provided to surround an outer circumference of the substrate placed on the spin chuck and guide the treatment liquid scattered from the substrate placed on the spin chuck to the cup body, and the supporting body may be provided to surround the spin chuck under the guide ring.

According to the exemplary embodiment of the present invention, wherein the supporting body may be formed with a discharge port for discharging the liquid scattered into the supporting body by the rotation of the spin chuck.

According to the exemplary embodiment of the present invention, wherein a plurality of discharge ports may be formed along a circumferential direction of the supporting body.

According to the exemplary embodiment of the present invention, wherein the discharge port may be provided as a slot whose longitudinal direction follows the circumferential direction of the supporting body.

According to the exemplary embodiment of the present invention, wherein a plurality of guide rings may be provided to be spaced apart from each other and stacked in the vertical direction.

According to the exemplary embodiment of the present invention, wherein the guide ring may be formed with an insertion groove into which the chuck pin is inserted.

According to the exemplary embodiment of the present invention, wherein an inner surface of the supporting body may has a shape corresponding to an outer surface of the spin chuck.

According to the exemplary embodiment of the present invention, wherein the inner surface of the supporting body may be provided to be adjacent to the outer surface of the spin chuck.

According to the exemplary embodiment of the present invention, wherein the driving assembly includes: a driving handle; a first driver for lifting the driving handle; a driven handle; a connecting body for connecting the driven handle and the supporting body; and a second driver for rotating the spin chuck to switch positions between a first position where the driving handle overlaps the driven handle and a second position where the driving handle and the driven handle deviate from each other when viewed from above, the driven handle is provided to be raised and lowered by the lifting of the driving handle at the first position, and the connecting body may be coupled to the supporting body under the spin chuck.

According to the exemplary embodiment of the present invention, wherein the guide ring is vertically moved between a raised position, which is higher than an upper surface of the spin chuck, and a lowered position, which is lower than the upper surface of the spin chuck, when the guide ring is located at the raised position, the chuck pin is located at a grip position to grip the substrate placed on the spin chuck, and when the guide ring is located at the lowered position, the chuck pin may be located at a release position to release the gripping of the substrate.

According to the exemplary embodiment of the present invention, wherein the support unit further includes a chuck pin moving assembly for moving the chuck pin between a standby position and a process position, the chuck pin moving assembly includes: a chuck pin support to which the chuck pin is coupled; and a pusher fixedly coupled to the connecting body, an inclined surface is formed in a region facing the pusher in the chuck pin support, and the pusher is in contact with the inclined surface when the guide ring is moved to the raised position, and pushes the chuck pin support along the inclined surface so that the chuck pin may be moved from the release position to the grip position.

An exemplary embodiment of the present disclosure, a support unit comprising: wherein the support unit includes: a spin chuck on which the substrate is placed and rotates; a chuck pin installed on the spin chuck to support a side of the substrate placed on the spin chuck; a guide ring installed on the spin chuck to rotate with the spin chuck; a supporting body for supporting the guide ring and having a cylindrical shape with open top and bottom portions; and a driving assembly for lifting the supporting body so that the guide ring moves relative to the spin chuck in a vertical direction, when viewed from above, the guide ring is provided to surround an outer circumference of the substrate placed on the spin chuck and guide the treatment liquid scattered from the substrate placed on the spin chuck to the cup body, and the supporting body may be provided to surround the spin chuck under the guide ring.

According to the exemplary embodiment of the present invention, wherein the supporting body is formed with a discharge port for discharging the liquid scattered by the rotation of the spin chuck, and a plurality of discharge ports is formed along a circumferential direction of the supporting body, and may be provided as a slot whose longitudinal direction follows the circumferential direction of the supporting body.

According to the exemplary embodiment of the present invention, wherein the guide ring may be formed with an insertion groove into which the chuck pin is inserted.

According to the exemplary embodiment of the present invention, wherein the inner surface of the supporting body has a shape corresponding to an outer surface of the spin chuck, and the inner surface of the supporting body may be provided to be adjacent to the outer surface of the spin chuck.

According to the exemplary embodiment of the present invention, wherein the driving assembly includes: a driving handle; a first driver for lifting the driving handle; a driven handle; a connecting body for connecting the driven handle and the supporting body; and a second driver for rotating the spin chuck to switch positions between a first position where the driving handle overlaps the driven handle and a second position where the driving handle and the driven handle deviate from each other when viewed from above, the driven handle is provided to be raised and lowered by the lifting of the driving handle at the first position, the connecting body is coupled to the supporting body under the spin chuck, and the guide ring is vertically moved between a raised position, which is higher than an upper surface of the spin chuck, and a lowered position, which is lower than the upper surface of the spin chuck, by the driving assembly.

According to the exemplary embodiment of the present invention, wherein the support unit further includes a chuck pin moving assembly for moving the chuck pin between a standby position and a process position, the chuck pin moving assembly includes: a chuck pin support to which the chuck pin is coupled; and a pusher fixedly coupled to the connecting body, an inclined surface is formed in a region facing the pusher in the chuck pin support, and the pusher is provided to be in contact with the inclined surface when the guide ring is moved to the raised position and to push the chuck pin support along the inclined surface, when the guide ring is located at the raised position, the chuck pin is located at a grip position to grip the substrate placed on the spin chuck, and when the guide ring is located at the lowered position, the chuck pin may be located at a release position to release the gripping of the substrate.

An exemplary embodiment of the present disclosure, an apparatus for processing a substrate, the apparatus comprising: a cup body for providing a treatment space for processing a substrate; a support unit for supporting and rotating the substrate in the treatment space; and a liquid supply unit for supplying a treatment liquid to an upper surface of the substrate supported by the support unit, wherein the support unit includes: a spin chuck on which the substrate is placed and rotates; a chuck pin installed on the spin chuck to support a side of the substrate placed on the spin chuck; a guide ring installed on the spin chuck to rotate with the spin chuck; a driving assembly for lifting the supporting body so that the guide ring moves relative to the spin chuck in a vertical direction; a chuck pin moving assembly for moving the chuck pin between a standby position and a process position; and a supporting body for supporting the guide ring and having a cylindrical shape with open top and bottom portions, when viewed from above, the guide ring is provided to surround an outer circumference of the substrate placed on the spin chuck and guide the treatment liquid scattered from the substrate placed on the spin chuck to the cup body, and the supporting body is provided to surround the spin chuck under the guide ring. the driving assembly includes: a driving handle; a first driver for lifting the driving handle; a driven handle; a connecting body for connecting the driven handle and the supporting body; and a second driver for rotating the spin chuck to switch positions between a first position where the driving handle overlaps the driven handle and a second position where the driving handle and the driven handle deviate from each other when viewed from above, the driven handle is provided to be raised and lowered by the lifting of the driving handle at the first position, the connecting body is coupled to the supporting body under the spin chuck, the guide ring is vertically moved between a raised position, which is higher than an upper surface of the spin chuck, and a lowered position, which is lower than the upper surface of the spin chuck, by the driving assembly, the chuck pin moving assembly includes: a chuck pin support to which the chuck pin is coupled; and a pusher fixedly coupled to the connecting body, an inclined surface is formed in a region facing the pusher in the chuck pin support, and the pusher is provided to be in contact with the inclined surface when the guide ring is moved to the raised position and to push the chuck pin support along the inclined surface, when the guide ring is located at the raised position, the chuck pin is located at a grip position to grip the substrate placed on the spin chuck, and when the guide ring is located in the lowered position, the chuck pin may be located at a release position to release the gripping of the substrate.

According to the exemplary embodiment of the present invention, wherein the supporting body is formed with a discharge port for discharging the liquid scattered by the rotation of the spin chuck, and a plurality of discharge ports is formed along a circumferential direction of the supporting body, and may be provided as a slot whose longitudinal direction follows the circumferential direction of the supporting body.

According to the exemplary embodiment of the present invention, wherein the guide ring may be formed with an insertion groove into which the chuck pin is inserted.

According to the exemplary embodiment of the present invention, it is possible to minimize deformation of a guide ring.

Further, according to the exemplary embodiment of the present invention, it is possible to improve apparatus and process stability.

Further, according to the exemplary embodiment of the present invention, it is possible to prevent a backflow, a wake, or an upward airflow from occurring around a spin chuck.

Further, according to the exemplary embodiment of the present invention, it is possible to prevent the generation of particles and contamination of a substrate.

Further, according to the exemplary embodiment of the present invention, it is possible to efficiently recover a treatment liquid scattered from a rotating substrate.

Further, according to the exemplary embodiment of the present invention, it is possible to discharge the treatment liquid to the outside of a supporting body even when the treatment liquid is scattered into the supporting body.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a top plan view schematically illustrating a substrate processing apparatus according to an exemplary embodiment of the present invention.

FIG. 2 is a diagram schematically illustrating a liquid treating chamber of FIG. 1 according to an exemplary embodiment.

FIG. 3 is a diagram schematically illustrating an exhaust path and a drainage path of the liquid treating chamber of FIG. 2.

FIG. 4 is a diagram schematically illustrating an exemplary embodiment of a support unit of FIG. 2.

FIG. 5 is a diagram illustrating an exemplary embodiment of an insertion groove formed in a guide ring and an insertion hole formed in a supporting body.

FIG. 6 is a diagram schematically illustrating an exemplary embodiment of a chuck pin moving assembly.

FIG. 7 is a diagram illustrating a process in which the chuck pin is moved by the chuck pin moving assembly.

FIG. 8 is a diagram illustrating a state in which the chuck pin is positioned at a grip position by the chuck pin moving assembly.

FIG. 9 is a diagram schematically illustrating the shape of a connecting body, the guide ring, and the supporting body.

FIG. 10 is a diagram illustrating a driving handle and a driven handle at a first position viewed from above.

FIG. 11 is a diagram illustrating a driving handle and a driven handle at a second position viewed from above.

FIGS. 12 and 13 are diagrams illustrating a process in which the chuck pin and the guide ring are simultaneously moved.

FIG. 14 is a diagram illustrating another exemplary embodiment of the chuck pin moving assembly.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer is described as an example as a target to be treated. However, the technical spirit of the present invention may be applied to apparatuses used for treating other types of substrates, other than wafers, as targets to be treated.

Hereinafter, an exemplary embodiment of the present invention will be described with reference to the accompanying drawings.

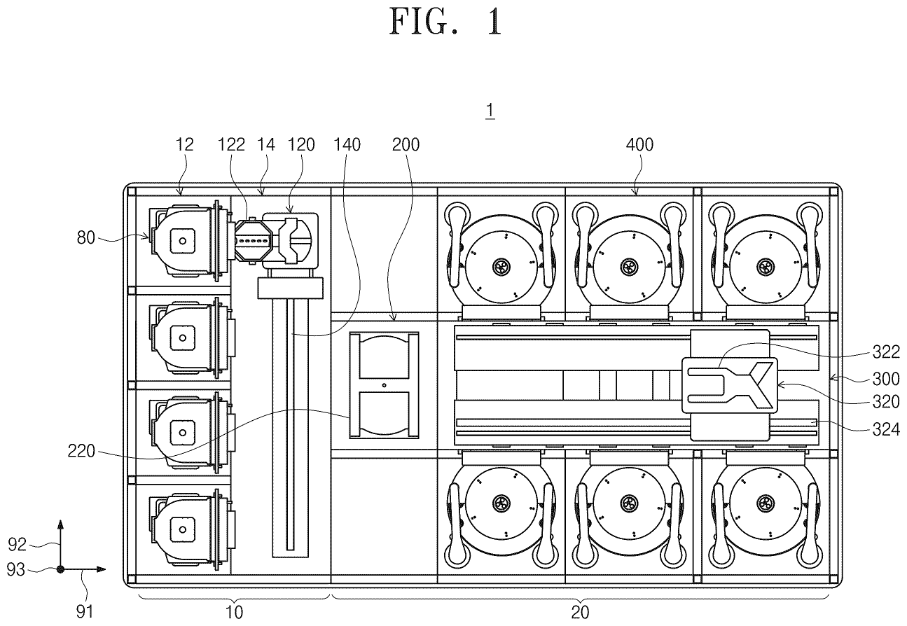

FIG. 1 is a top plan view schematically illustrating a substrate treating apparatus according to an exemplary embodiment of the present invention. Referring to FIG. 1, a substrate processing apparatus includes an index module 10, a treating module 20, and a controller 30. According to the exemplary embodiment, the index module 10 and the treating module 20 are disposed along one direction. Hereinafter, the direction in which the index module 10 and the treating module 20 are disposed is referred to as a first direction 91, and when viewed from above, a direction perpendicular to the first direction 91 is referred to as a second direction 92, and a direction perpendicular to both the first direction 91 and the second direction 92 is referred to as a third direction 93.

The index module 10 transfers a substrate W from a container 80 in which the substrate W is accommodated to the treating module 20, and makes the substrate W, which has been completely processed in the treating module 20, be accommodated in the container 80. A longitudinal direction of the index module 10 is provided in the second direction 92. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plurality, and the plurality of load ports 12 may be disposed in the second direction 92.

As the container 80, an airtight container, such as a Front Open Unified Pod (FOUP), may be used. The container 80 may be placed on the load port 12 by a transfer means (not illustrated), such as an overhead transfer, an overhead conveyor, or an automatic guided vehicle, or an operator.

An index robot 120 is provided to the index frame 14. A guide rail 140 of which a longitudinal direction is the second direction 92 is provided within the index frame 14, and the index robot 120 may be provided to be movable on the guide rail 140. The indexing robot 120 includes a hand 122 on which the substrate W is placed, and the hand 122 may be provided to be movable forward and backward, rotatable about the third direction 93, and movable along the third direction 93. A plurality of hands 122 are provided to be spaced apart in the vertical direction, and the hands 122 may move forward and backward independently of each other.

The treating module 20 includes a buffer unit 200, a transfer chamber 300, and a treating chamber 400. The buffer unit 200 provides a space in which the substrate W loaded into the treating module 20 and the substrate W unloaded from the treating module 20 stay temporarily. The treating chamber 400 performs a treatment process of liquid-treating the substrate W by supplying a liquid onto the substrate W. The transfer chamber 300 transfers the substrate W between the buffer unit 200 and the liquid treating chamber 400.

The transfer chamber 300 may be provided so that a longitudinal direction is the first direction 91. The buffer unit 200 may be disposed between the index module 10 and the transfer chamber 300. A plurality of liquid treating chambers 400 may be provided and may be disposed on the side portion of the transfer chamber 300. The liquid treating chamber 400 and the transfer chamber 300 may be disposed in the second direction 92. The buffer unit 200 may be located at one end of the transfer chamber 300.

According to the example, the liquid treating chambers 400 are respectively disposed on opposite sides of the transfer chamber 300. At one side of the transfer chamber 300, the liquid treating chambers 400 may be provided in an array of A×B (A and B are each 1 or a natural number larger than 1) in the first direction 91 and the third direction 93.

The transfer chamber 300 includes a transfer robot 320. A guide rail 340 having a longitudinal direction in the first direction 91 is provided in the transfer chamber 300, and the transfer robot 320 may be provided to be movable on the guide rail 340. The transfer robot 320 includes a hand 322 in which the substrate W is placed, and the hand 322 may be provided to be movable forwardly and backwardly, rotatable about the third direction 93, and movable along the third direction 93. A plurality of hands 322 are provided to be spaced apart in the vertical direction, and the hands 322 may move forward and backward independently of each other.

The buffer unit 200 includes a plurality of buffers 220 on which the substrate W is placed. The buffers 220 may be disposed while being spaced apart from each other in the third direction 93. A front face and a rear face of the buffer unit 200 are opened. The front face is a face facing the index module 10, and the rear face is a face facing the transfer unit 300. The index robot 120 may approach the buffer unit 200 through the front face, and the transfer robot 320 may approach the buffer unit 200 through the rear face.

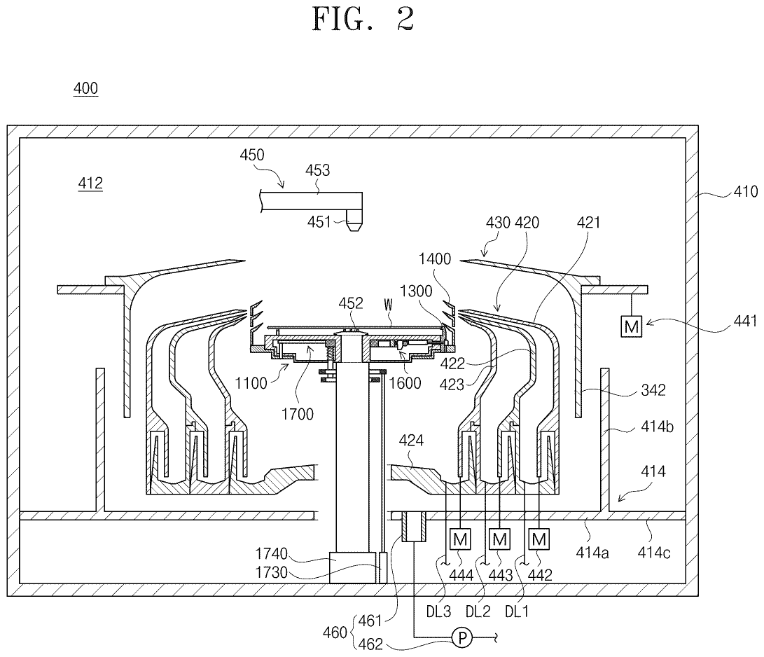

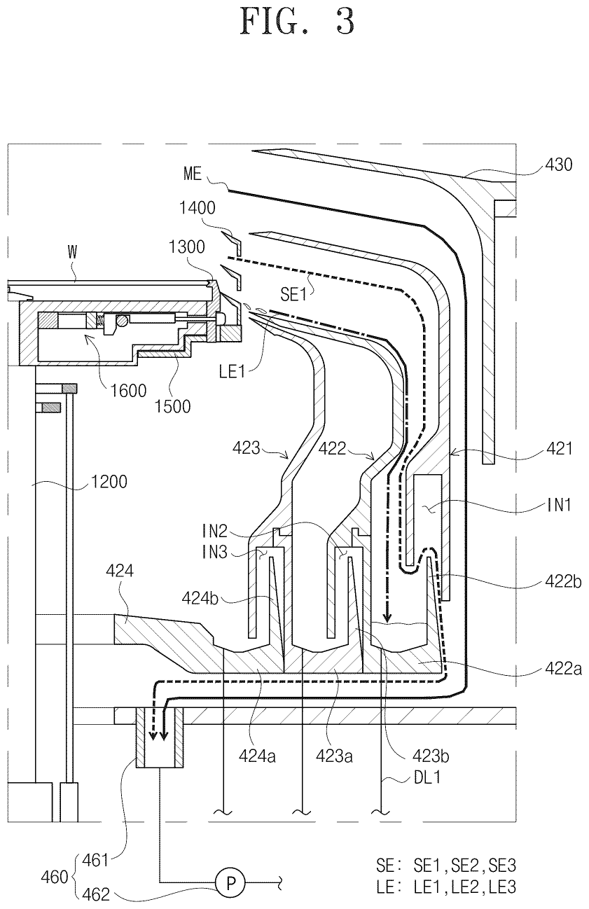

FIG. 2 is a diagram schematically illustrating the liquid treating chamber of FIG. 1 according to the exemplary embodiment, and FIG. 3 is a diagram schematically illustrating an exhaust path and a drainage path of the liquid treating chamber of FIG. 2. Referring to FIGS. 2 and 3, the liquid treating chamber 400 includes a housing 410, a treating bowl 420, an exhaust bowl 430, a plurality of lifting mechanisms 441, 442, 443, and 444, a liquid supply unit 450, an exhaust unit 460, a support unit 1000, and a controller.

The housing 410 is provided in a generally rectangular parallelepiped shape. The housing provides an inner space 412. The components to be described below may be disposed in the housing 410. An opening (not illustrated) provided as a passage of the substrate W may be formed in the side of the housing 410. An exhaust path forming member 414 may be provided in the inner space 412 provided by the housing 410.

The exhaust path forming member 414 may include a first part 414a extending in the horizontal direction from the lower side of the treating bowl 420 to be described later, a second part 414b extending in the vertical direction from the outside of the exhaust bowl 430, and a third part 414c extending in the horizontal direction from the outside of the second part 414b.

When viewed from the top, the exhaust path forming member 414 may have a plate shape in which a circular hole is formed in a central region. The exhaust path forming member 414 may be combined with the treating bowl 420 to define a main exhaust path ME and a sub exhaust path SE. Also, unlike the treating bowl 420 and the exhaust bowl 430, the height of the exhaust path forming member 414 may be fixed and provided. Also, a rotation shaft 1200 of a spin chuck 1100, which will be described later, may be inserted into and provided in a hole formed in a central region of the exhaust path forming member 414.

The treating bowl 420 may recover the treatment liquid supplied by the liquid supply unit 450. The treating bowl 420 may exhaust the airflow around the substrate W. The treating bowl 420 may provide a liquid recovery path and an airflow exhaust path. The treatment liquid supplied by the liquid supply unit 450 may be recovered through the liquid recovery path, and the airflow around the substrate W may be exhausted to the outside of the liquid treating chamber 400 through the airflow exhaust path.

The treating bowl 420 may include a first bowl 421, a second bowl 422, a third bowl 423, and a liquid receiving member 424. The first bowl 421, the second bowl 422, the third bowl 423, and the liquid receiving member 424 may have a ring shape surrounding the periphery of the spin chuck 1100. Also, the first bowl 421, the second bowl 422, and the third bowl 423 may be provided in a structure in which upper portions thereof are stacked on each other.

The first bowl 421 may be an outer bowl. The first bowl 421 may be a bowl disposed at the outermost side among the plurality of bowls included in the treating bowl 420. The first bowl 421 may be provided in a shape in which upper and lower portions are open. A first insertion groove IN1 may be formed inside the first bowl 421 at a lower end of the first bowl 421. An outer wall 422b of a first liquid receiving part 422a formed outside a lower end of the second bowl 422 may be inserted into the first insertion groove IN1.

The second bowl 422 may be an intermediate bowl. The second bowl 422 may be a bowl placed between the outermost bowl and the innermost bowl among a plurality of bowls included in the treating bowl 420. The second bowl 422 may be provided in a shape in which upper and lower portions are open. A second insertion groove IN2 may be formed in the lower end of the second bowl 422 toward the inner side of the second bowl 422. An outer wall 423b of a second liquid receiving part 423a formed outside the lower end of the third bowl 423 may be inserted into the second insertion groove IN2.

The third bowl 423 may be an inner bowl. The third bowl 423 may be a bowl disposed at the innermost side among the plurality of bowls included in the treating bowl 420. The third bowl 423 may be provided in a shape in which upper and lower portions are open. A third insertion groove IN3 may be formed at a lower end of the third bowl 423 toward the third bowl 423. An outer wall 424b of a third liquid receiving part 424a formed outside the liquid receiving member 424 may be inserted into the third insertion groove IN3.

The liquid receiving member 424 may be provided inside the third bowl 423. The liquid receiving member 424 may be provided at the same height as the first liquid receiving part 421a and the second liquid receiving part 422a. The third liquid receiving part 424a may be formed outside the liquid receiving member 424.

A first drain line DL1 may be connected to the second bowl 422, a second drain line DL2 may be connected to the third bowl 423, and a third drain line DL3 may be connected to the liquid receiving member 424. Each of the first to third drain lines DL1, DL2, and DL3 may drain the treatment liquid recovered through the liquid receiving part to the outside of the substrate processing apparatus 400. The first to third drain lines DL1, DL2, and DL3 may also recover different types of treatment liquid or, in some cases, may recover the same type of treatment liquid.

Also, the first bowl 421, the second bowl 422, and the third bowl 423 may be configured to be lifted. The first bowl 421, the second bowl 422, and the third bowl 423 may be configured to be lifted by the second lifting mechanism 442, the third lifting mechanism 443, and the fourth lifting mechanism 444, respectively. The second lifting mechanism 442, the third lifting mechanism 443, and the fourth lifting mechanism 444 may be a mechanism capable of generating lifting driving force capable of lifting the first bowl 421, the second bowl 422, and the third bowl 423, such as a motor or air/hydraulic cylinder. As the first bowl 421, the second bowl 422, and the third bowl 423 are selectively lifted, a plurality of sub-exhaust paths SE and a plurality of liquid recovery paths LE may be formed. For example, when the first bowl 421 rises, the first sub-exhaust path SE1 and the first liquid recovery path LE1 may be formed, when the first bowl 421 and the second bowl 422 rise, the second sub-exhaust path SE2 and the second liquid recovery path LE2 may be formed, and when the first bowl 421, the second bowl 422, and the third bowl 423 rise, the third sub-exhaust path SE3 and the third liquid recovery path LE3 may be formed.

The exhaust bowl 430 may be installed to be spaced apart from the outside of the treating bowl 420. The exhaust bowl 430 may be disposed to be spaced apart from the outer bowl 421, which is the outermost bowl among the plurality of bowls of the treating bowl 420. The exhaust bowl 430 may be disposed to be spaced apart from the outer bowl 421 to define at least a portion of the main exhaust path ME that exhausts the peripheral airflow of the substrate W placed on the spin chuck 1100. The exhaust bowl 430 may be configured to be lifted by the first lifting mechanism 441. The first lifting mechanism 441 may include a lifting motor. However, the present invention is not limited thereto, and the first lifting mechanism 441 may use a pneumatic cylinder or a hydraulic cylinder as a configuration for generating lifting driving force.

The liquid supply unit 450 supplies a treatment liquid to a substrate supported by the support unit 1000. The liquid supply unit 450 includes a first nozzle 451 and a second nozzle 452. The first nozzle 451 supplies a first treatment liquid to the upper surface of the substrate W supported by the chuck pin 1300. The first nozzle 451 is supported by a nozzle support 453. The nozzle support 453 moves the first nozzle 451 between a process position and a standby position. In the process position, the first nozzle 451 supplies the first treatment liquid to the substrate W placed on the spin chuck 1100, and the nozzle 451 which has completed supplying the first treatment liquid waits in the standby position. According to an example, the first treatment liquid may be chemical or ultrapure water. The second nozzle 452 may be provided as a back nozzle. When the second nozzle 452 is provided as a back nozzle, the second nozzle 452 is installed on an upper surface of the spin chuck 1100 to be described later. Also, a through-hole 1100a for installing a back nozzle may be formed in the center of the spin chuck 1100. The second nozzle 452 supplies a second treatment liquid to a bottom surface of the substrate W supported by the chuck pin 1300. According to an example, the second treatment liquid may be ultrapure water.

The exhaust unit 460 provides the depressurization to the inner space 412. The exhaust unit 460 provides the depressurization to exhaust the peripheral airflow of the substrate W to the outside of the liquid treating chamber 400. The exhaust unit 460 may include an exhaust port 461 and an exhaust device 462.

The exhaust port 461 may be connected to a first portion 414a of the exhaust path forming member 414. When viewed from above, the exhaust port 461 may be disposed closer to the rotation shaft 1200 than the treating bowl 420 and the exhaust bowl 430. Also, the inlet of the exhaust port 461 may be configured to exhaust airflow introduced into the exhaust path defined by a space between the treating bowl 420 and the first portion 414a of the exhaust path forming member 414. The inlet of the exhaust port 461 may be provided to face a space between the exhaust path forming member 414 and the first portion 414a.

The exhaust device 462 may be a device capable of providing depressurization to the inner space 412 through the exhaust port 461. The exhaust device 462 may be a pump. However, the present invention is not limited thereto, and the exhaust device 462 may be modified into various known devices capable of providing depressurization to the inner space 412.

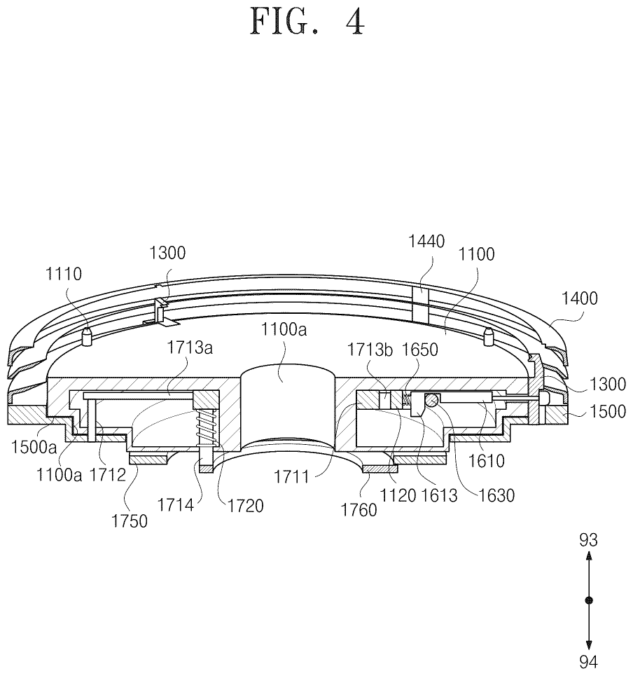

The support unit 1000 supports the substrate W in a treatment space. FIG. 4 is a diagram schematically illustrating an exemplary embodiment of the support unit of FIG. 2. Referring to FIG. 4, the support unit 1000 includes the spin chuck 1100, the rotation shaft 1200, the chuck pin 1300, a guide ring 1400, a supporting body 1500, a chuck pin moving assembly 1600, and a driving assembly 1700.

The spin chuck 1100 supports the substrate W. The upper surface of the spin chuck 1100 is provided in a generally circular shape, and may have a diameter larger than that of the substrate W. Hereinafter, a radial direction away from a center of the spin chuck 1100 will be referred to as a fifth direction 95, and an opposite direction will be referred to as a sixth direction 96. A support pin 1110 for supporting a rear surface of the substrate W is provided on an upper surface of the spin chuck 1100. A plurality of support pins 1110 is provided. The support pins 1110 are arranged to have an annular ring shape as a whole by a combination thereof. The support pin 1110 is provided such that an upper end thereof protrudes from the spin chuck 1100 so that the substrate W is spaced apart from the spin chuck 1100 by a predetermined distance. A space is formed inside the spin chuck 1100. A chuck pin moving assembly 1600 to be described later may be installed inside the spin chuck 1100.

The rotation shaft 1200 is provided to be rotatable by a second driver 1740. The rotation shaft 1200 is fixedly coupled to the center of the bottom surface of the spin chuck 1100. Accordingly, the spin chuck 1100 may be rotated by the second driver 1740.

The chuck pin 1300 is provided on a side surface of the spin chuck 1100. A plurality of chuck pins 1300 is provided. The chuck pin 1300 is disposed along the circumferential direction of the spin chuck 1100. A groove is formed in an upper portion of the chuck pin 1300. The groove is formed to face the substrate W. Also, the groove is formed at a position higher than the upper surface of the spin chuck 1000. Accordingly, the chuck pin 1300 supports the side surface of the substrate W at the side portion of the substrate W.

The chuck pin 1300 is installed in the chuck pin moving assembly 1600 installed inside the spin chuck 1100. The chuck pin 1300 may be moved by the chuck pin moving assembly 1600. The chuck pin 1300 is provided to be movable between a grip position G1 and a release position G2. The chuck pin 1300 is moved toward the substrate W when moved to the grip position G1. Alternatively, the chuck pin 1300 is moved in the sixth direction 96. The substrate W is handed over from the support pin 1110 to the chuck pin 1300 while the chuck pin 1300 is moved to the grip position G1. Then, the chuck pin 1300 grips a side surface of the substrate W. Accordingly, the substrate W is supported by the chuck pin 1300. When the chuck pin 1300 moves to the release position G2, the chuck pin 1300 moves in a direction spaced apart from the substrate W. Alternatively, the chuck pin 1300 moves in the fifth direction 95. Accordingly, the grip on the substrate W by the chuck pin 1300 is released. As the chuck pin 1300 moves to the release position G2, the substrate W is handed over from the chuck pin 1300 to the support pin 1110. Furthermore, the support pin 1110 supports a rear surface of the substrate W. Details on the driving of the chuck pin 1300 by the chuck pin moving assembly 1600 will be described later.

The guide ring 1400 guides the treatment liquid scattered from the substrate W to the cup body 420. The guide ring 1400 may be provided between the spin chuck 1100 and the cup body 420. The guide ring 1400 may be provided adjacent to the spin chuck 1100. The guide ring 1400 may be provided to surround the spin chuck 1100. The guide ring 1400 may be provided to be inclined downward in a direction away from the spin chuck 1100. In addition, the guide ring 1400 may be provided to be inclined downward in two stages.

The guide ring 1400 includes an upper ring 1410, an intermediate ring 1420, a lower ring 1430, and a fixed rod 1440. The upper ring 1410, the intermediate ring 1420, and the lower ring 1430 are provided to overlap when viewed from above. The upper ring 1410 is located above the intermediate ring 1420. The intermediate ring 1420 is located between the upper ring 1410 and the lower ring 1430. The lower ring 1430 is located at a position facing the upper ring in the vertical direction. The lower ring 1430, the intermediate ring 1420, and the upper ring 1410 are sequentially located along the third direction 93. The upper ring 1410, the intermediate ring 1420, and the lower ring 1430 are coupled to the fixed rod 1440. The fixed rod 1440 may be provided to penetrate the edge regions of the upper ring 1410, the intermediate ring 1420, and the lower ring 1430 in the third direction 93.

The supporting body 1500 is provided to surround a lower portion of the spin chuck 1100. The supporting body 1500 is provided in a continuous shape. The supporting body 1500 is provided in a cylindrical shape with open upper and lower portions. The supporting body 1500 is located under the guide ring 1400. The guide ring 1400 is installed above the supporting body 1500. The guide ring 1400 is coupled to have a continuous coupling point with the supporting body 1500. Accordingly, even when the spin chuck 1100 rotates, stress applied to the coupling point may be dispersed, and deformation and vibration of the guide ring 1400 due to excessive stress may be suppressed.

Furthermore, the inner surface of the supporting body 1500 is provided to have a shape corresponding to the outer surface of the spin chuck 1100. Furthermore, an inner surface 1500a of the supporting body 1500 is provided to be adjacent to an outer surface 1100a of the spin chuck 1100. According to an example, the inner surface 1500a of the supporting body 1500 and the outer surface 1100a of the spin chuck 1100 may be formed to be stepped, and the respective stepped surfaces may be provided to be adjacent to each other. Accordingly, the space occupied by the supporting body 1500 may be minimized.

A discharge port 1510 is formed in the supporting body 1500. When the treatment liquid is not guided to the cup body 420 through the guide ring 1400 and is scattered to the supporting body 1500, the treatment liquid is discharged to the outside of the supporting body 1500 through the discharge port 1510. The discharge port may be provided in a slot shape. A longitudinal direction of the discharge port 1510 may be provided in the same manner as the circumferential direction of the supporting body 1500. A plurality of discharge ports 1510 may be provided. The discharge port 1510 may be formed along the circumferential direction of the supporting body 1500.

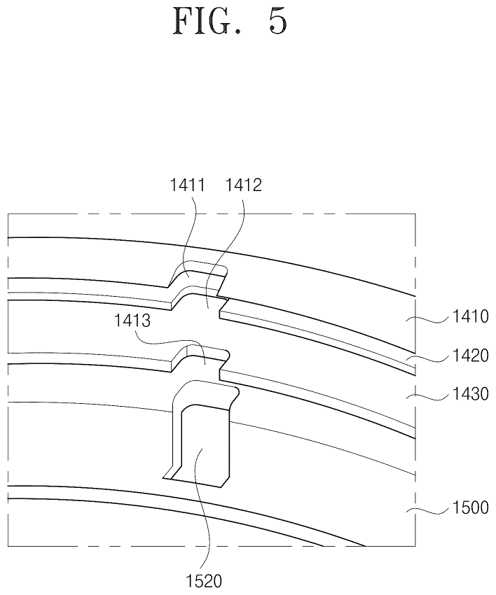

FIG. 5 is a diagram illustrating an exemplary embodiment of an insertion groove formed in the guide ring and an insertion hole formed in the support. Referring to FIG. 5, when the guide ring 1400 and the supporting body 1500 are provided to be adjacent to the spin chuck 1100, the guide ring 1400 and the supporting body 1500 may interfere with the chuck pin 1300. In order to minimize interference between the chuck pin 1300, and the guide ring 1400 and the supporting body 1500, an insertion groove 1401 may be formed in the guide ring 1400, and an insertion hole 1520 may be formed in the supporting body 1500.

The insertion groove 1401 may be formed such that the chuck pin 1300 is located. The insertion groove 1401 may be formed in a direction from the inside to the outside of the guide ring 1400.

A plurality of insertion grooves 1401 may be provided. The insertion groove 1401 may be formed along the circumferential direction of the guide ring 1400. The insertion groove 1401 is formed at a position corresponding to the position of the chuck pin 1300. When a plurality of guide rings 1410, 1420, and 1430 is provided, insertion grooves 1411, 1421, and 1431 may be formed in the guide rings 1410, 1420, and 1430, respectively.

The insertion port 1520 may be formed such that a lower portion of the chuck pin 1300 is inserted. A plurality of insertion ports 1520 may be provided. The insertion ports 1520 may be provided in a number corresponding to the number of chuck pins 1300. The insertion port 1520 may be formed along the circumferential direction of the supporting body 1500. The insertion port 1520 may be formed at a position corresponding to the chuck pin 1300.

Interference between the chuck pin 1300, the guide ring 1400 and the supporting body 1500 may be minimized by the insertion groove 1401 and the insertion port 1520, and the guide ring 1400 may be installed to be closer to the substrate W. Accordingly, the guide ring 1400 may guide the treatment liquid scattered from the substrate W to be efficiently directed toward the cup body 420.

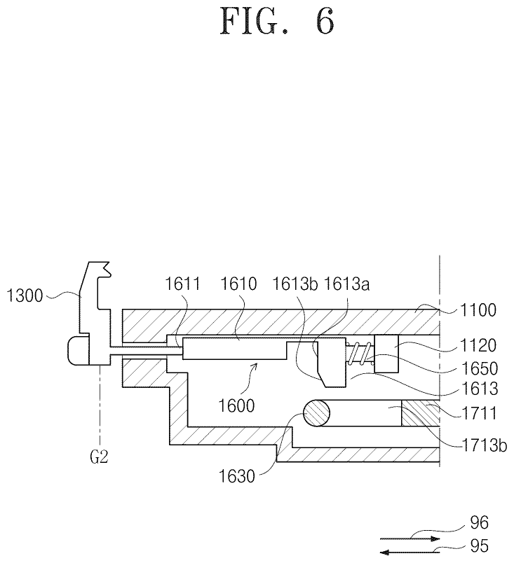

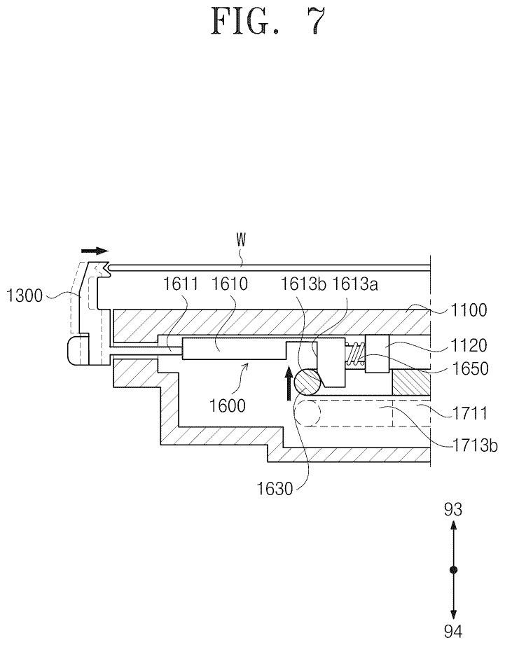

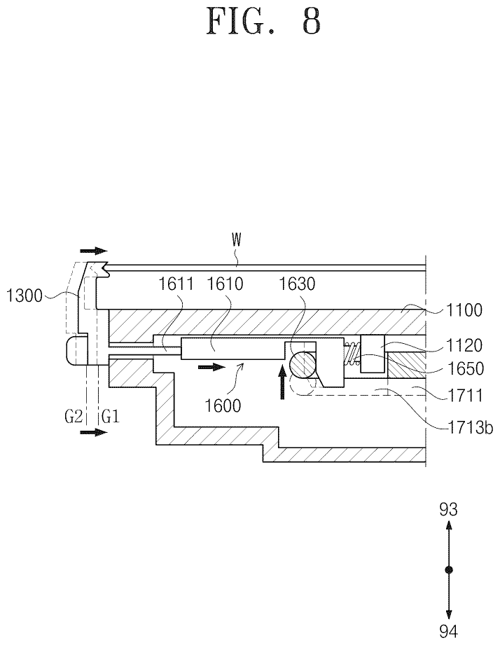

FIG. 6 is a diagram schematically illustrating an exemplary embodiment of the chuck pin moving assembly, FIG. 7 is a diagram illustrating a process in which the chuck pin is moved by the chuck pin moving assembly, and FIG. 8 is a diagram illustrating a state in which the chuck pin is positioned at the grip position by the chuck pin moving assembly. Referring to FIGS. 6 to 8, the chuck pin moving assembly 1600 is installed inside the spin chuck 1100. The chuck pin moving assembly 1600 may be provided to move the chuck pin 1300 by the CAM structure. The chuck pin moving assembly 1600 may include a chuck pin support 1610, a pusher 1630, and a first elastic member 1650.

The chuck pin support 1610 supports the chuck pin 1300. The chuck pin support 1610 has a radial direction of the spin chuck 1300 as a longitudinal direction. Also, the chuck pin support 1610 is provided to reciprocate in the fifth direction 95 and the sixth direction 96. According to an example, a guide member (not illustrated) is provided on the spin chuck 1300, and the chuck pin support 1300 may be installed on the guide member.

The chuck pin support 1610 has a support rod 1611 and the support rod 1611 is provided to penetrate the sidewall of the spin chuck 1300 and protrude outward. The chuck pin 1300 is fixedly coupled to the support rod 1611. Accordingly, the chuck pin 1300 is moved together when the chuck pin support 1610 is moved.

Also, the chuck pin support 1610 has a contact portion 1613. The contact portion 1613 has a shape protruding downward from the chuck pin support 1610. The contact portion 1613 has a vertical surface 1613a and an inclined surface 1613a. The vertical surface 1613a and the inclined surface 1613a are combined with each other to form a continuous surface. The vertical surface 1613a is formed to extend in a vertical direction from a lower surface of the chuck pin support 1610. The vertical surface 1613a may have a quadrangular shape. The inclined surface 1613b is formed to extend from a lower end of the vertical surface 1613a. The inclined surface 1613b is provided to have an inclination with respect to the vertical direction. The inclination is formed so that a width of the inclined surface 1613b decreases as it goes down to a lower portion of the contact portion 1613 in the cross section in the longitudinal direction of the chuck pin support 1610.

The pusher 1630 is provided at a position corresponding to the inclined surface 1613b. The pusher 1630 is provided so as to partially overlap the inclined surface 1613b when viewed from above. A surface of the pusher 1630 corresponding to the inclined surface 1613b may have a curved surface. According to an example, a vertical cross section of the pusher 1630 may be a circle. The pusher 1630 is provided to be vertically movable. The pusher 1630 is provided to ascend to a position that is in contact with the vertical surface 1613a and descend to a position that is spaced apart from the contact portion 1613. According to an example, the pusher 1630 is installed on a connecting body 1710 to be described later, and may be vertically moved together with the connecting body 1710. When the pusher 1630 ascends, the pusher 1630 contacts the inclined surface 1613b and the vertical surface 1613a in order of the inclined surface 1613b and the vertical surface 1613a. When the pusher 1630 ascends, the pusher 1630 applies force in the third direction 93 with respect to the inclined surface 1613b while being in contact with the inclined surface 1613b. Since the direction of the force is not provided perpendicular to the direction of inclination of the inclined surface 1613b, the force by the pusher 1630 is not offset, and the force in the sixth direction 96 pushes the inclined surface 1613b. Accordingly, the chuck pin support 1610 is moved in the sixth direction 96. The pusher 1630 ascends to the height at which the vertical surface 1613a is located. At the same time, the chuck pin 1300 is moved to the grip position G1, and the chuck pin 1300 grips the substrate W.

The first elastic member 1650 is installed at one side of the chuck pin support 1610. A fixed structure 1120 fixed to the spin chuck 1100 is formed inside the spin chuck 1100, and one end of the first elastic member 1650 is coupled to the fixed structure 1120. Further, the other end of the first elastic member 1650 is coupled to the chuck pin support 1610. The first elastic member 1650 is installed to push the chuck pin support 1610 in the fifth direction 95. The first elastic member 1650 is provided to be compressed while the chuck pin 1300 moves to the grip position G1 when the pusher 1630 ascends. The first elastic member 1650 is provided to apply elastic force in the fifth direction 95 when the chuck pin 1300 is positioned at the grip position. Accordingly, when the pusher 1630 descends, the chuck pin 1300 is moved in the fifth direction 95 by elastic force. Further, the chuck pin 1300 is moved from the grip position G1 to the release position G2. According to an example, the first elastic member 1650 may be a spring.

Referring back to FIG. 5, the driving assembly 1700 moves the guide ring 1400 and the chuck pin 1300. The chuck pin 1300 may be moved together when the guide ring 1400 is moved. When the chuck pin 1300 is moved to the grip position G1, the guide ring 1400 may be moved to the process position. Also, when the chuck pin 1300 is moved to the release position G2, the guide ring 1400 may be moved to the standby position P2. The process position P1 is a position where the guide ring 1400 is raised and is located higher than the upper surface of the spin chuck 1100. The standby position P2 is a position where the guide ring 1400 is lowered and is located lower than the upper surface of the spin chuck 1100.

The driving assembly 1700 may include the connecting body 1710, a second elastic member 1720, a first driver 1730, a second driver 1740, a driving handle 1750, and a driven handle 1760.

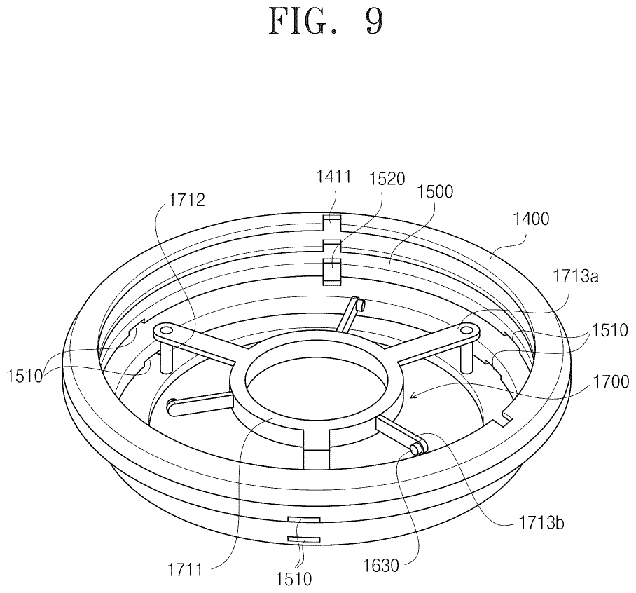

FIG. 9 is a diagram schematically illustrating the shape of the connecting body, the guide ring, and the support. Referring to FIG. 9, the connecting body 1710 is provided inside the spin chuck 1100. The connecting body 1710 has a ring structure 1711, a fixed rod 1712, a spoke 1713, and a connection rod 1714.

The ring structure 1711 is provided in a shape surrounding the through-hole 1110a. The connection rod 1714 is installed under the ring structure 1711. The connection rod 1714 has a shape that protrudes and extends from the ring structure 1711 in the vertical direction. The connection rod 1714 is provided to penetrate the lower wall of the spin chuck 1100 and protrude from the spin chuck 1100. The driven handle 1760 to be described later is coupled to a lower end of the connection rod 1714. Also, the connection rod 1714 may be provided to be inserted into the second elastic member 1720.

The spoke 1713 has a shape radiating from the ring structure 1711. A plurality of spokes 1713 may be provided. A plurality of spokes 1713 include a plurality of first spokes 1713a and a plurality of second spokes 1713b. The first spoke 1713a and the second spoke 1713b are provided so as to have a predetermined interval. The first spoke 1713a and the second spoke 1713b are provided to be spaced apart from each other. The length of the second spoke 1713b may be shorter than the length of the first spoke 1713a.

The fixed rod 1712 is installed on the first spoke 1713a. The fixed rod 1712 has a shape extending in the vertical direction from the distal end of the first spoke 1713a. The fixed rod 1712 is provided to penetrate the lower wall of the spin chuck 1100. The supporting body 1500 is coupled to the lower end of the fixed rod 1712. Accordingly, when the connecting body 1710 is moved, the guide ring 1400 and the supporting body 1500 may be moved together.

The above-described pusher 1630 is coupled to the second spoke 1713b. The pusher 1630 may be coupled to have a shape extending from the distal end of the second spoke 1713b to the side surface of the second spoke 1713b. The second spoke 1713b may be provided in a shape extending up to a position where the coupled pusher 1630 overlaps a part of the inclined surface 1613a, and overlaps the vertical surface 1613b. Accordingly, when the connecting body 1710 is moved, the chuck pin 1300 may be moved together.

The second elastic member 1720 is provided to raise the connecting body 1710. One end of the second elastic member 1720 is provided to be coupled to the lower wall of the spin chuck 1100, and the other end thereof is provided to be coupled to the ring structure 1711. When the connecting body 1710 is lowered, the second elastic member 1720 is compressed. Therefore, the second elastic member may apply elastic force in a direction in which the connecting body 1710 is raised. According to an example, the second elastic member 1720 is provided as a spring, and the connection rod 1714 may be inserted.

The first driver 1730 drives the supporting body 1500 to move up and down. According to an example, the first driver 1730 may be a cylinder or an actuator. The second driver 1740 rotates the rotation shaft 1200. When the rotation shaft 1200 rotates, the spin chuck 1100 coupled to the rotation shaft 1200 rotates together. Also, the driven handle 1760 coupled to the spin chuck 1100 rotates together. The second driver 1740 may be a motor.

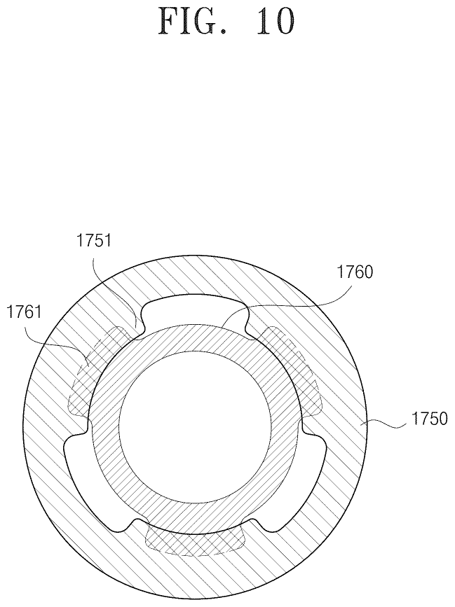

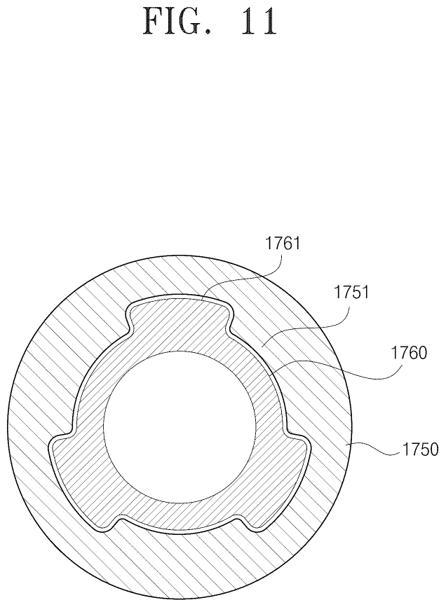

FIG. 10 is a diagram illustrating the driving handle and the driven handle at a first position viewed from above, and FIG. 11 is a diagram illustrating the driving handle and the driven handle at a second position viewed from above. Referring to FIGS. 10 and 11, the driving handle 1750 and the driven handle 1760 may be provided in a ring shape. The diameter of the driving handle 1750 may be larger than the diameter of the driven handle 1760. The driving handle 1750 may be located outside the driven handle 1760. The driving handle 1750 and the driven handle 1760 may be concentric. Accordingly, the driven handle 1760 may be provided in a shape surrounding the rotation shaft 1200, and the driving handle 1750 may be provided in a shape surrounding the driven handle 1760. Also, the inner circumference of the driving handle 1750 and the outer circumference of the driven handle 1760 may be provided in a shape engaged with each other. According to an example, the outer circumference of the driven handle 1760 and the inner circumference of the driving handle 1750 may be formed in a sawteeth shape engaged with each other.

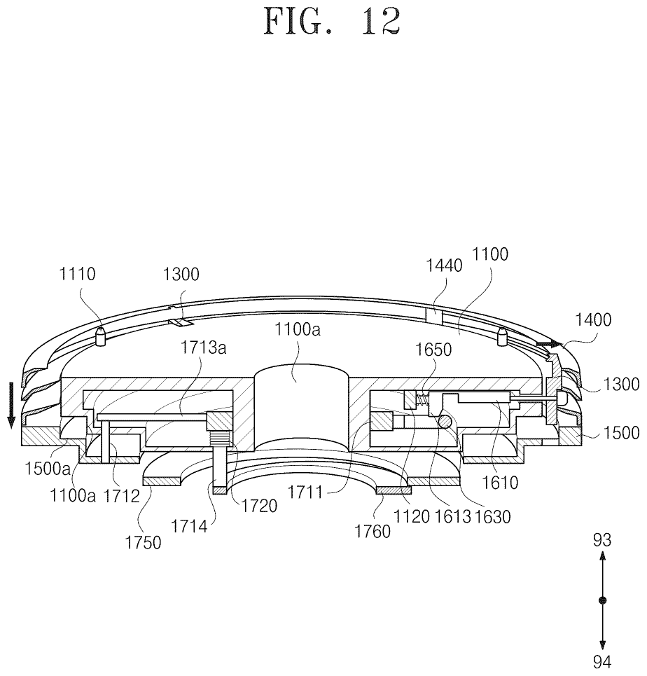

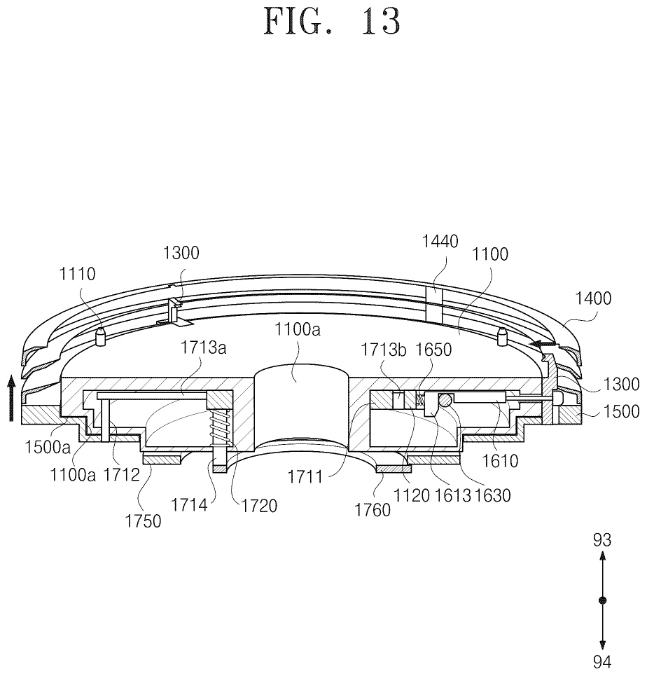

FIGS. 12 and 13 are diagrams illustrating a process in which the chuck pin and the guide ring are simultaneously moved. Referring to FIGS. 12 and 13, the driving handle 1750 is vertically moved by the first driver 1730. Relative heights of the driving handle 1750 and the driven handle 1760 may be adjusted by the first driver 1730. When the driving handle 1750 and the driven handle 1760 are spaced apart from each other, the driven handle 1760 may be rotated together with the rotation of the spin chuck 1100. Accordingly, when viewed from above, a sawteeth-shaped protrusion 1751 of the driving handle 1750 and a sawteeth-shaped protrusion 1761 of the driven handle 1760 may overlap each other. Hereinafter, the position where the sawteeth-shaped protrusion 1751 of the driving handle 1750 and the sawteeth-shaped protrusion 1761 of the driven handle 1760 overlap each other is referred to as a first position R1, and the position where the sawteeth-shaped protrusion 1751 of the driving handle 1750 and the sawteeth-shaped protrusion 1761 of the driven handle 1760 do overlap each other is referred to as a second position R2.

The driving handle 1750 moves the driven handle 1760. When the driving handle 1750 and the driven handle 1760 are positioned at the first position R1, and when the driving handle 1750 is moved downward, the sawteeth-shaped protrusion 1751 of the driving handle 1750 and the sawteeth-shaped protrusion 1761 of the driven handle 1760 come into contact with each other. The driving handle 1750 moves the driven handle 1760 downward while further moving downward. Accordingly, the connecting body 1710 to which the driven handle 1760 is coupled is moved downward, and the supporting body 1500 to which the connecting body 1710 is coupled is moved downward. Accordingly, the guide ring 1400 is moved from the process position P1 to the standby position P2. Furthermore, while the connecting body 1710 is moved downward, the pusher 1630 is moved downward. The pusher 1630 is spaced apart from the contact portion 1613. Accordingly, the chuck pin support 1610 is moved in the fifth direction 95 by the first elastic member 1650, and the chuck pin 1300 is moved from the grip position G1 to the release position G2.

Furthermore, when the first driver 1730 raises the driving handle 1750, the connecting body 1710 is raised upward by the second elastic member 1720. The driving handle 1750 is raised until being spaced apart from the driven handle 1760, and accordingly, the guide ring 1400 is moved from the standby position P2 to the process position P1. Furthermore, the chuck pin support 1610 is moved in the sixth direction 96 by the pusher 1630, and the chuck pin 1300 is moved from the release position G2 to the grip position G1.

According to an the exemplary embodiment of the present invention, since the supporting body 1500 is provided in a continuous shape, deformation of the guide ring 1400 due to the stress and vibration generated during rotation may be minimized by distributing the stress generated by the supporting body 1500. In addition, the stress applied to the insertion groove 1410 and the insertion hole 1520 may be minimized. Accordingly, stability of the apparatus and the process may be improved.

In addition, according to the exemplary embodiment of the present invention, the resistance between the supporting body 1500 and the air may be minimized by providing the support 1500 in a continuous shape to prevent air from being positioned on the rotation path of the supporting body 1500, and the occurrence of a backflow, a wake, and an upward airflow around the support 1500 may be suppressed. Accordingly, contamination of the substrate W may be prevented by suppressing the movement of particles to the substrate W by a backflow, a wake, and an upward airflow.

In addition, according to the exemplary embodiment of the present invention, even when the treatment liquid is scattered into the supporting body 1500, the treatment liquid may be discharged to the outside of the supporting body 1500 through the discharge port 1510 to prevent the treatment liquid from becoming fixed.

In the above-described example, the present invention has been described based on the case where only the first nozzle is provided for supplying the treatment liquid to the upper surface of the substrate W as an example. However, the present invention is not limited thereto, and a plurality of nozzles may be provided to supply the treatment liquid to the upper surface of the substrate W. In this case, the added nozzle may supply another type of treatment liquid to the substrate. Furthermore, the added nozzles are supported by different arms, and may be moved independently. Selectively, the first nozzle 452 and the added nozzle may be mounted on the same arm and moved simultaneously.

Further, in the above-described example, the present invention has been described based on the case where only the substrate W is treated with the treatment liquid as an example. However, the present invention is not limited thereto, and a configuration of injecting drying gas onto the substrate W may be further added so that the treatment liquid may be dried.

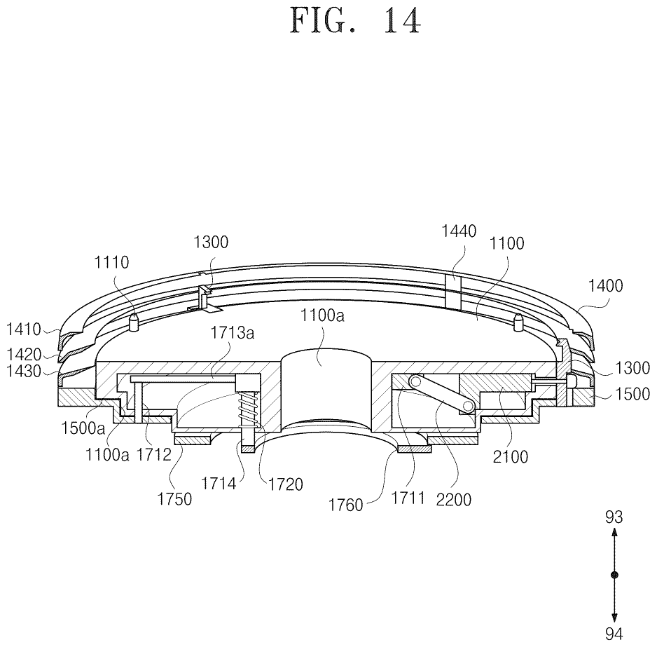

Also, in the above example, the present invention has been described based on the case where the chuck pin moving assembly 1600 has a CAM structure as an example. However, the present invention is not limited thereto, and the chuck pin moving assembly 1600 may also be provided to have a link structure as illustrated in FIG. 14. In this case, the chuck pin moving assembly 2000 may include a first link 2100 that moves left and right and a second link 2200 that moves up and down, and the first link 2100 and the second link 2200 may be provided to be pivotally coupled.

It should be understood that exemplary embodiments are disclosed herein and other modifications may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present disclosure, and all such modifications that would be obvious to one of ordinary skill in the art are intended to be included within the scope of the accompanying claims.

What is claimed is:

1. An apparatus for processing a substrate, the apparatus comprising:
a cup body for providing a treatment space for processing a substrate;
a support unit for supporting and rotating the substrate in the treatment space; and
a liquid supply unit for supplying a treatment liquid to an upper surface of the substrate supported by the support unit,
wherein the support unit includes:
a spin chuck on which the substrate is placed and rotates;
a chuck pin installed on the spin chuck to support a side of the substrate placed on the spin chuck;
a guide ring installed on the spin chuck to rotate with the spin chuck;
a supporting body for supporting the guide ring and having a cylindrical shape with open top and bottom portions; and
a driving assembly for lifting the supporting body so that the guide ring moves relative to the spin chuck in a vertical direction,
when viewed from above, the guide ring is provided to surround an outer circumference of the substrate placed on the spin chuck and guide the treatment liquid scattered from the substrate placed on the spin chuck to the cup body, and
the supporting body is provided to surround the spin chuck under the guide ring.

2. The apparatus of claim 1, wherein the supporting body is formed with a discharge port for discharging the liquid scattered into the supporting body by the rotation of the spin chuck.

3. The apparatus of claim 2, wherein a plurality of discharge ports is formed along a circumferential direction of the supporting body.

4. The apparatus of claim 3, wherein the discharge port is provided as a slot whose longitudinal direction follows the circumferential direction of the supporting body.

5. The apparatus of claim 1, wherein a plurality of guide rings is provided to be spaced apart from each other and stacked in the vertical direction.

6. The apparatus of claim 2, wherein the guide ring is formed with an insertion groove into which the chuck pin is inserted.

7. The apparatus of claim 6, wherein an inner surface of the supporting body has a shape corresponding to an outer surface of the spin chuck.

8. The apparatus of claim 7, wherein the inner surface of the supporting body is provided to be adjacent to the outer surface of the spin chuck.

9. The apparatus of claim 1, wherein the driving assembly includes:
a driving handle;
a first driver for lifting the driving handle;
a driven handle;
a connecting body for connecting the driven handle and the supporting body; and
a second driver for rotating the spin chuck to switch positions between a first position where the driving handle overlaps the driven handle and a second position where the driving handle and the driven handle deviate from each other when viewed from above,
the driven handle is provided to be raised and lowered by the lifting of the driving handle at the first position, and
the connecting body is coupled to the supporting body under the spin chuck.

10. The apparatus of claim 1, wherein the guide ring is vertically moved between a raised position, which is higher than an upper surface of the spin chuck, and a lowered position, which is lower than the upper surface of the spin chuck,
when the guide ring is located at the raised position, the chuck pin is located at a grip position to grip the substrate placed on the spin chuck, and
when the guide ring is located at the lowered position, the chuck pin is located at a release position to release the gripping of the substrate.

11. The apparatus of claim 10, wherein the support unit further includes a chuck pin moving assembly for moving the chuck pin between a standby position and a process position,
the chuck pin moving assembly includes:
a chuck pin support to which the chuck pin is coupled; and
a pusher fixedly coupled to the connecting body,
an inclined surface is formed in a region facing the pusher in the chuck pin support, and
the pusher is in contact with the inclined surface when the guide ring is moved to the raised position, and pushes the chuck pin support along the inclined surface so that the chuck pin is moved from the release position to the grip position.

12. A support unit comprising:
a spin chuck on which the substrate is placed and rotates;
a chuck pin installed on the spin chuck to support a side of the substrate placed on the spin chuck;
a guide ring installed on the spin chuck to rotate with the spin chuck;
a supporting body for supporting the guide ring and having a cylindrical shape with open top and bottom portions; and
a driving assembly for lifting the supporting body so that the guide ring moves relative to the spin chuck in a vertical direction,
when viewed from above, the guide ring is provided to surround an outer circumference of the substrate placed on the spin chuck and guide the treatment liquid scattered from the substrate placed on the spin chuck to the cup body, and
the supporting body is provided to surround the spin chuck under the guide ring.

13. The support unit of claim 12, wherein the supporting body is formed with a discharge port for discharging the liquid scattered by the rotation of the spin chuck, and
a plurality of discharge ports is formed along a circumferential direction of the supporting body, and is provided as a slot whose longitudinal direction follows the circumferential direction of the supporting body.

14. The support unit of claim 13, wherein the guide ring is formed with an insertion groove into which the chuck pin is inserted.

15. The support unit of claim 14, wherein the inner surface of the supporting body has a shape corresponding to an outer surface of the spin chuck, and
the inner surface of the supporting body is provided to be adjacent to the outer surface of the spin chuck.

16. The support unit of claim 12, wherein the driving assembly includes:
a driving handle;
a first driver for lifting the driving handle;
a driven handle;
a connecting body for connecting the driven handle and the supporting body; and
a second driver for rotating the spin chuck to switch positions between a first position where the driving handle overlaps the driven handle and a second position where the driving handle and the driven handle deviate from each other when viewed from above,
the driven handle is provided to be raised and lowered by the lifting of the driving handle at the first position,
the connecting body is coupled to the supporting body under the spin chuck, and
the guide ring is vertically moved between a raised position, which is higher than an upper surface of the spin chuck, and a lowered position, which is lower than the upper surface of the spin chuck, by the driving assembly.

17. The support unit of claim 16, wherein the support unit further includes a chuck pin moving assembly for moving the chuck pin between a standby position and a process position,
the chuck pin moving assembly includes:
a chuck pin support to which the chuck pin is coupled; and
a pusher fixedly coupled to the connecting body,
an inclined surface is formed in a region facing the pusher in the chuck pin support, and
the pusher is provided to be in contact with the inclined surface when the guide ring is moved to the raised position and to push the chuck pin support along the inclined surface,
when the guide ring is located at the raised position, the chuck pin is located at a grip position to grip the substrate placed on the spin chuck, and
when the guide ring is located at the lowered position, the chuck pin is located at a release position to release the gripping of the substrate.

18. An apparatus for processing a substrate, the apparatus comprising:
a cup body for providing a treatment space for processing a substrate;
a support unit for supporting and rotating the substrate in the treatment space; and
a liquid supply unit for supplying a treatment liquid to an upper surface of the substrate supported by the support unit,
wherein the support unit includes:
a spin chuck on which the substrate is placed and rotates;
a chuck pin installed on the spin chuck to support a side of the substrate placed on the spin chuck;
a guide ring installed on the spin chuck to rotate with the spin chuck;
a driving assembly for lifting the supporting body so that the guide ring moves relative to the spin chuck in a vertical direction;
a chuck pin moving assembly for moving the chuck pin between a standby position and a process position; and
a supporting body for supporting the guide ring and having a cylindrical shape with open top and bottom portions,
when viewed from above, the guide ring is provided to surround an outer circumference of the substrate placed on the spin chuck and guide the treatment liquid scattered from the substrate placed on the spin chuck to the cup body, and
the supporting body is provided to surround the spin chuck under the guide ring.
the driving assembly includes:
a driving handle;
a first driver for lifting the driving handle;
a driven handle;
a connecting body for connecting the driven handle and the supporting body; and
a second driver for rotating the spin chuck to switch positions between a first position where the driving handle overlaps the driven handle and a second position where the driving handle and the driven handle deviate from each other when viewed from above,
the driven handle is provided to be raised and lowered by the lifting of the driving handle at the first position,
the connecting body is coupled to the supporting body under the spin chuck,
the guide ring is vertically moved between a raised position, which is higher than an upper surface of the spin chuck, and a lowered position, which is lower than the upper surface of the spin chuck, by the driving assembly,
the chuck pin moving assembly includes:
a chuck pin support to which the chuck pin is coupled; and
a pusher fixedly coupled to the connecting body,
an inclined surface is formed in a region facing the pusher in the chuck pin support, and
the pusher is provided to be in contact with the inclined surface when the guide ring is moved to the raised position and to push the chuck pin support along the inclined surface,
when the guide ring is located at the raised position, the chuck pin is located at a grip position to grip the substrate placed on the spin chuck, and
when the guide ring is located in the lowered position, the chuck pin is located at a release position to release the gripping of the substrate.

19. The apparatus of claim 18, wherein the supporting body is formed with a discharge port for discharging the liquid scattered by the rotation of the spin chuck, and
a plurality of discharge ports is formed along a circumferential direction of the supporting body, and is provided as a slot whose longitudinal direction follows the circumferential direction of the supporting body.

20. The apparatus of claim 19, wherein the guide ring is formed with an insertion groove into which the chuck pin is inserted.
